(19) United States
(12) Patent Application Publication
(10) Pub. No.: US 2015/0349180 A1
(43) Pub. Date: Dec. 3, 2015

(54) RELATIVE DOPANT CONCENTRATION LEVELS IN SOLAR CELLS

(71) Applicants: David D. Smith, Campbell, CA (US); Staffan Westerberg, Sunnyvale, CA (US)

(72) Inventors: David D. Smith, Campbell, CA (US); Staffan Westerberg, Sunnyvale, CA (US)

(21) Appl. No.: 14/292,454

(22) Filed: May 30, 2014

(51) Int. Cl. H01L 31/065; H01L 31/0288; H01L 31/18; H01L 31/0368

(52) U.S. Cl. CPC H01L 31/065; H01L 31/03682; H01L 31/0288; H01L 31/1868; H01L 31/182

(57) ABSTRACT

A solar cell may include a substrate having a front side facing the sun to receive solar radiation during normal operation and a backside opposite the front side. The solar cell may further include a polysilicon layer formed over the backside of the substrate. A P-type diffusion region and an N-type diffusion region may be formed in the polysilicon layer to provide a butting PN junction. The P-type diffusion region may have a first dopant concentration level and the N-type diffusion region may have a second dopant concentration level such that the first dopant concentration level is less than the second dopant concentration level.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a PN junction between P-type and N-type diffusion regions. Solar radiation impinging on the surface of, and entering into, the substrate of the solar cell creates electron and hole pairs in the bulk of the substrate. The electron and hole pairs migrate to P-type diffusion and N-type diffusion regions in the substrate, thereby creating a voltage differential between the diffusion regions. The diffusion regions are connected to conductive regions on the solar cell to direct an electrical current from the solar cell to an external circuit. In a backside contact solar cell, for example, both the diffusion regions and the interdigitated metal contact fingers coupled to them are on the backside of the solar cell. The contact fingers allow an external electrical circuit to be coupled to and be powered by the solar cell.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

### BRIEF DESCRIPTION OF THE DRAWINGS

FIG. 1 illustrates a cross-sectional view of a portion of example solar cell having a butting PN junction formed between P-type and N-type diffusion regions formed above a substrate, according to some embodiments.

FIG. 2 is a flowchart illustrating an example method of forming a backside contact solar cell with a lower P-type dopant concentration level, according to one embodiment.

FIG. 3 is a flowchart illustrating an example method of forming a backside contact solar cell with a lower P-type dopant concentration level, according to one embodiment.

FIGS. 4-9 illustrate cross-sectional views of forming a backside contact solar cell having a butting PN junction formed between P-type and N-type diffusion regions formed on a substrate, according to some embodiments.

FIG. 10 is a flowchart illustrating an example method of forming a backside contact solar cell with a lower P-type dopant concentration level, according to one embodiment.

FIGS. 11-16 illustrate cross-sectional views of forming a backside contact solar cell having a butting PN junction formed between P-type and N-type diffusion regions formed using counter doping on a substrate, according to some embodiments.

FIG. 17 is a flowchart illustrating an example method of forming a backside contact solar cell with a lower P-type dopant concentration level by printing P-type and N-type dopant sources, according to one embodiment.

FIGS. 18-22 illustrate cross-sectional views of forming a backside contact solar cell having a butting PN junction formed between P-type and N-type diffusion regions formed by printing on a substrate, according to some embodiments.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” dopant source does not necessarily imply that this dopant source is the first dopant source in a sequence; instead the term “first” is used to differentiate this dopant source from another dopant source (e.g., a “second” dopant source).

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Although much of the disclosure is described in terms of solar cells for ease of understanding, the disclosed techniques and structures apply equally to other semiconductor structures (e.g., silicon wafers generally).

In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as lithography techniques, are not described in detail in order to not unnecessarily obscure embodiments of the present disclosure. Furthermore, it is to be understood that the various embodiments shown in the figures are illustrative representations and are not necessarily drawn to scale.

This specification first describes an example solar cell that can include the disclosed dopant levels, followed by a more detailed explanation of various embodiments of forming dual dopant level solar cell structures. Various examples are provided throughout.

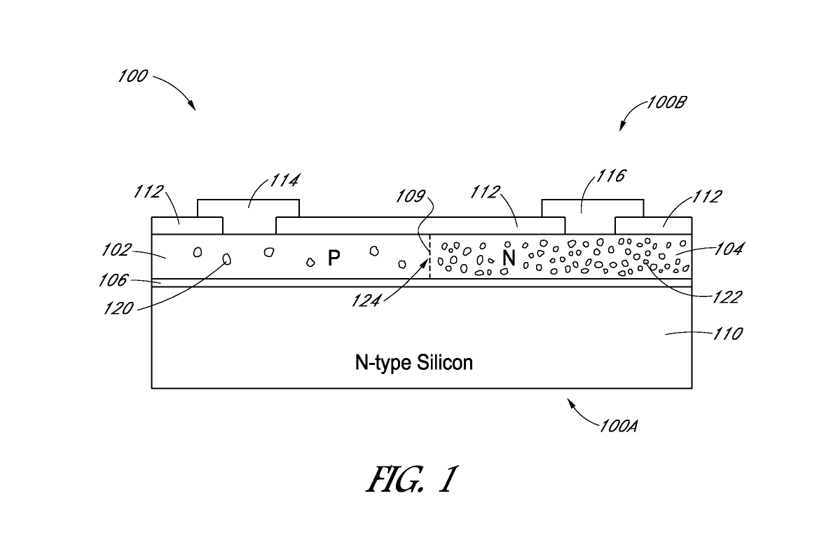

Referring to FIG. 1, a cross-sectional view of a solar cell 100 having a front side 100A facing the sun to receive solar radiation during normal operation and a backside 100B opposite the front side is shown. The backside 100B of the solar cell 100, in one embodiment, includes a P-type diffusion polysilicon region 102 and an N-type diffusion polysilicon region 104 disposed above a dielectric layer 106 and forming a butting PN junction 109 on a portion of a substrate 110. One example of the substrate 110 include N-type Silicon. Generally speaking, the P-type diffusion polysilicon region 102 and the N-type diffusion polysilicon region 104 at the butting junction 109 form a diode. The P-type and N-type diffusion polysilicon regions 102, 104 may be formed in a polysilicon layer. The diffusion regions may be formed by depositing doped silicon dioxide layers over an un-doped polysilicon layer and performing a diffusion step, or by depositing an un-doped polysilicon layer followed by a dopant implantation step, for example. In a specific embodiment, the P-type diffusion polysilicon region 102 and the N-type diffusion polysilicon region 104 are formed above the surface of the substrate 110 or external to a solar cell substrate.

The solar cell 100 may further include conductive contacts formed on emitter regions which are formed above the substrate 110, in accordance with an embodiment. A first electrically conductive contact such as a first metal contact finger 114 may be disposed in a first contact opening disposed in a silicon nitride layer 112 and may be coupled to the P-type diffusion polysilicon region 102. A second electrically conductive contact such as a second metal contact finger 116 may be disposed in a second contact opening disposed in the silicon nitride layer 112 and may be coupled to the N-type diffusion polysilicon region 104. The “fingers” may be made using masks and etch or according to other techniques.

In one embodiment, the P-type diffusion polysilicon region 102 and the N-type diffusion polysilicon region 104 can provide emitter regions for solar cell 100. Thus, in an embodiment, the first metal contact finger 114 and the second metal contact finger 116 are disposed on respective emitter regions. In an embodiment, the first metal contact finger 114 and the second metal contact finger 116 are back contacts for a back-contact solar cell and are situated on a surface of the solar cell opposing a light receiving surface (side 100A) of solar cell 100. Furthermore, in one embodiment, the emitter regions are formed on a thin or tunnel dielectric layer such as the dielectric layer 106.

According to some embodiments, as shown in FIG. 1, fabricating a back-contact solar cell can include forming the thin dielectric layer 106 on the substrate 110. In one embodiment, a thin dielectric layer is composed of silicon dioxide and has a thickness approximately in the range of 5-50 Angstroms. In one embodiment, thin dielectric layer performs as a tunnel oxide layer. In an embodiment, the substrate 110 is a bulk mono-crystalline silicon substrate, such as an N-type doped mono-crystalline silicon substrate. However, in another embodiment, the substrate includes a polycrystalline silicon layer disposed on a global solar cell substrate.

In a back-contact solar cell, such as the solar cell 100, with interdigitated N-type and P-type diffusions in a polysilicon layer there is the butting PN junction 109 that may be formed within the polysilicon layer at an interface between the two diffusions. The butting PN junction 109 is the area between the Boron doped (P-type) polysilicon and the Phosphorous doped (N-type) polysilicon. The butting PN junction 109 can extend into both sides of the physical interface between the P-type and N-type diffusion regions. The widths and how much it extends into each side of the physical junction depend on doping concentration levels and gradient of each side of the butting PN junction 109.

Generally, space charge recombination happens at the poly grain boundaries at the PN junction 109. Space charge recombination is a process by which mobile charge carriers (electrons and electron holes) are eliminated. It is a process by which a conduction band electron loses energy and re-occupies the energy state of an electron hole in the valence band. The poly-crystalline silicon of the polysilicon layer consists of grains. Each grain has a perfect crystalline lattice with all Si atoms lined up. However, different grains may have different orientation and between the grains there is a boundary where the crystallinity of the material is broken. This interface is called a grain boundary. Electron hole recombination has increased probability in certain areas of the material such as the grain boundary. For example metal defects increase recombination. The inventors found that the Boron at the grain boundaries is one such area where there is a higher recombination. If those areas are reduced the lifetime of the material is higher and there is a better chance of collecting the carriers.

Because the butting PN junction 109 has a high recombination in most cases it prevents reaching high device efficiencies beyond 20%. However, the inventors found that space charge recombination can depend on P-type dopant concentration levels. By lowering the dopant concentration level to ˜5E17/cm3 in the polysilicon layer the Boron atoms at the grain boundaries are few enough that recombination is suppressed to levels where high efficiency devices can be made.

Consistent with one embodiment, the P-type diffusion polysilicon region 102 may be formed by a P-type dopant source 120 having a first dopant concentration level and the N-type diffusion polysilicon region 104 may be formed by an N-type dopant source 122 having a second dopant concentration level such that the first dopant concentration level is less than the second dopant concentration level. For example, the P-type diffusion polysilicon region 102 may be formed in the polysilicon layer by a P-type dopant source that comprises Boron having a dopant concentration level less than a range 1E17/cm3-1E18/cm3 so that the P-type diffusion polysilicon region 102 has a resulting dopant concentration level less than a range ˜5E19/cm3 to ˜5E17/cm3. Likewise, an N-type dopant source that comprises Phosphorus may be used to form the N-type diffusion polysilicon region 104. A dopant source is a source of charge carrier impurity atoms for a substrate such Boron is for a silicon based substrate. For example, in one embodiment, the charge carrier impurity atoms are N-type dopants, such as but not limited to phosphorus dopants. In another embodiment, the charge carrier impurity atoms are P-type dopants, such as but not limited to boron dopants.

In one embodiment, the P-type diffusion polysilicon region 102 and N-type diffusion polysilicon region 104 are active regions. Conductive contacts may be coupled to the active regions and separated from one another by isolation regions, which may be composed of a dielectric material. In an embodiment, the solar cell is a back-contact solar cell and further includes an anti-reflective coating layer (e.g., dielectric 112) disposed on a light-receiving surface, such as on a random textured surface of the solar cell.

The first dopant concentration level of the P-type dopant source 120 may be less than the second dopant concentration level of the N-type dopant source 122 to reduce recombination at the butting PN junction 109 to an extent that a resulting device efficiency is greater than 20%. For example, an N-type dopant source that comprises Phosphorus with a dopant concentration level greater than approximately 1E19/cm3-1E20/cm3 may be used to form the N-type diffusion polysilicon region 104 in the polysilicon layer compared to the P-type dopant source of Boron with a dopant concentration level less than approximately 1E17/cm3-1E18/cm3.

By reducing the P-type dopant concentration level to a lower concentration level the recombination is lowered so high efficiency solar cells can be made. In some embodiments, there is no need to physically separate N-type and P-type diffusions with a trench in order to decrease the recombination. By reducing recombination at the butting PN junction 109 without requiring a physical trench, at least two steps can be removed in the fabrication process of the solar cell 100 thus driving down the cost.

Additional increase in lifetime may be achieved by passivation of grain boundaries using Hydrogen (H). That is, further improvement in recombination can be achieved by passivating the now vacant sites at the grain boundaries with Hydrogen (H). This can be done during forming gas anneal (“FGA”) driving H from a nearby silicon nitride layer or by plasma enhanced chemical vapor deposition (PECVD) H (e.g., prior to nitride deposition).

Lowering the Boron doping concentration level can aid the effect of H passivation. For example, with lower Boron levels, hydrogenation (e.g., H passivation of any dangling Si bonds at the surface) can result in a higher cell lifetime. In contrast, with higher Boron concentrations the Boron atoms can take up a lot of the dangling bonds. However, at lower concentrations, H is now able to reach those bonds and passivate them.

For example, in one embodiment, H passivation can be performed by forming gas anneal (FGA) with a N2 and H2 mixture. Traditionally, the H in the forming gas is the source of H but an alternate source of H is from a silicon nitride PECVD layer or film that may be deposited on top of the polysilicon layer. The silicon nitride PECVD layer or film itself can have a lot of H and can be used to diffuse to a boundary region of the butting PN junction 109 and improve passivation during the anneal resulting in a passivation region 124. As the Boron levels at the interface or the butting PN junction 109 are lowered H is now able to get to the dangling Si bonds and passivate them.

As shown in FIG. 1, a dielectric in the form of the silicon nitride layer 112 may extend over the P-type diffusion polysilicon region 102 and the N-type diffusion polysilicon region 104. In one embodiment, the silicon nitride layer 112 is formed to a thickness of about 400 Angstroms by plasma enhanced chemical vapor deposition (PECVD).

Turning now to FIG. 2, a flow chart illustrating a method for forming a solar cell is shown, according to an embodiment. As shown at 202, a layer of polysilicon can be deposited, printed or implanted over a semiconductor region. Or, in some embodiments, the polysilicon can be formed from amorphous silicon converted into polysilicon. As described herein in FIG. 1, a pre-doped polysilicon layer is shown.

As shown at 204, the P-type diffusion polysilicon region 102, as shown in FIG. 1, can be formed from a P-type doped region. The P-type diffusion polysilicon region 102 may be formed by a P-type dopant source having a dopant concentration level A present in the P-type doped region. As shown at 206, from an N-type doped region the N-type diffusion polysilicon region 104, as shown in FIG. 1, can be formed by an N-type dopant source having a dopant concentration level B present in the N-type doped region. The dopant concentration level A of the P-type dopant source is less than the dopant concentration level B of the N-type dopant source. For example, the dopant concentration level A of Boron may be 1E17/cm3-1E18/cm3 such that the resultant doping concentration level in the P-type diffusion polysilicon region 102 may be ˜5E19/cm3-5E17/cm3 and the dopant concentration level B of Phosphorous may be 1E19/cm3-1E20/cm3 in the N-type dopant source. In one embodiment, a ˜2 order of magnitude difference in Boron and Phosphorus doping can be kept such that concentration ratio from P-type to N-type is 1:100. As shown at 208, Hydrogen H may be used to passivate at least some of the dangling Si bonds at the butting PN junction 109.

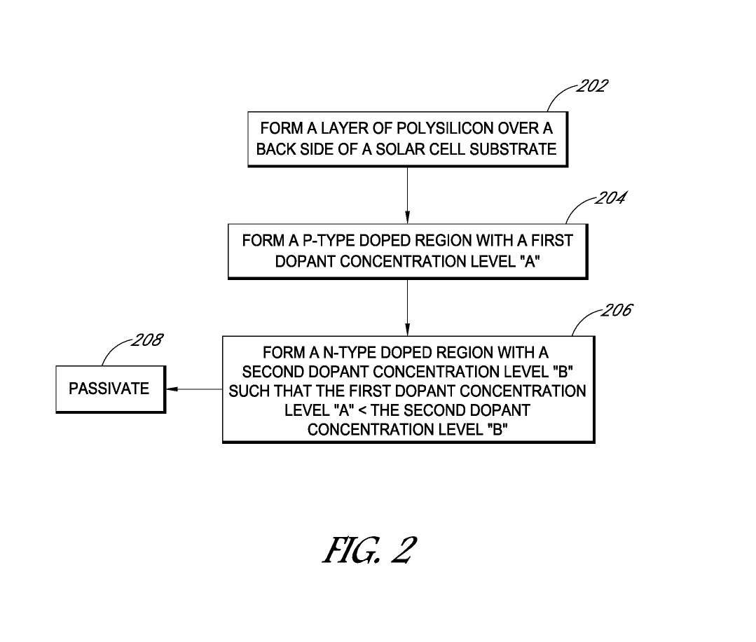

Referring to FIG. 3, a flowchart 300 is shown that represents operations in a method of forming P-type and N-type diffusion regions for a back-contact solar cell, in accordance with an embodiment. FIGS. 4-9 illustrate cross-sectional views of various stages in the fabrication of a back-contact solar cell, corresponding to operations of flowchart 300, in accordance with an embodiment of the present invention. In this example, the mentioned process steps are performed in the order shown. In other examples, the process steps can be performed in other orders. It is to be noted that other process steps not necessary for understanding are omitted in the interest of clarity. For example, other process steps, such as formation of metal contacts to the P-type and N-type diffusion regions, follow the passivation step to complete the fabrication of the solar cell. In addition, in some embodiments, the process can include fewer than all the illustrated steps.

Referring to operation 302 of the flowchart 300, and to corresponding FIG. 4, a method of forming a butting PN junction 411 (See FIG. 8) for a back-contact solar cell includes forming a thin dielectric layer 402 on a backside surface of the substrate 400. As illustrated, FIG. 4 shows a solar cell substrate 400 having a backside 405 and a front side 406. There are a plurality of P-type diffusion regions and N-type diffusion regions in a solar cell but only one of each is shown as being fabricated in the following example for clarity of illustration.

In an embodiment, the thin dielectric layer 402 is composed of silicon dioxide and has a thickness approximately in the range of 5-50 Angstroms (e.g., 20 Angstroms). In one embodiment, the dielectric layer 402 comprises silicon dioxide thermally grown on the surface of the substrate 400. The dielectric layer 402 may also comprise silicon nitride, for example. The thin dielectric layer 402 performs as a tunneling oxide layer. In a specific embodiment, the dielectric layer 402 is an anti-reflective coating (ARC) layer. In an embodiment, the substrate 400 is a bulk single-crystal substrate, such as an N-type doped single crystalline silicon substrate or N-type silicon wafer. However, in an alternative embodiment, the substrate 400 may include a polycrystalline silicon layer disposed on a global solar cell substrate.

Referring to operation 304 of the flowchart 300, and to corresponding FIG. 4, forming an undoped poly-crystalline silicon (polysilicon) layer 404 on the thin dielectric layer 402 is shown. It is to be understood that use of the term polysilicon layer is intended to also cover material that can be described as amorphous- or α-silicon. The polysilicon layer 404 may be formed to a thickness of about 2000 Angstroms by low-pressure chemical vapor deposition (LPCVD), for example.

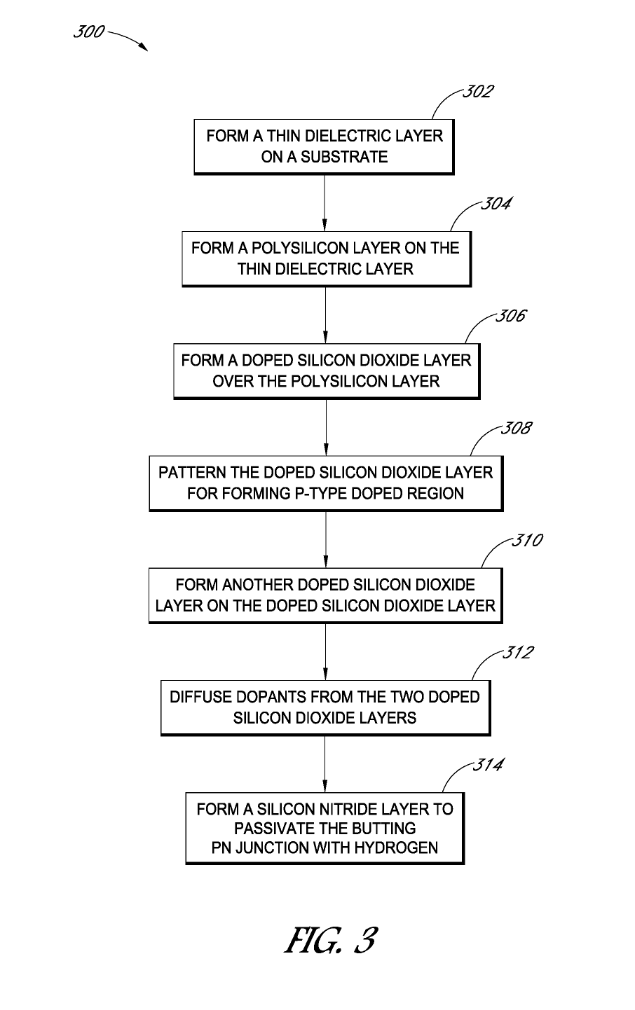

Referring to operation 306 of the flowchart 300, and to corresponding FIGS. 5-6, forming a first doped silicon dioxide layer 407 of FIG. 5 and patterning (operation 308 of flowchart 300) a first dopant source 408 of a first conductivity type such as P-type (e.g., Boron) on the polysilicon layer 404 is shown. The first doped silicon dioxide layer 407 serves as a dopant source for a subsequently formed diffusion region, which is a P-type diffusion region 414 in this example (see FIG. 8). The first doped silicon dioxide layer 407 may thus be doped with a P-type dopant, such as Boron. The first doped silicon dioxide layer 407 is patterned to remain over an area of the polysilicon layer 404 where the P-type diffusion region 414 is to be formed (FIG. 6). The first doped silicon dioxide layer 407 may be formed to a thickness of about 1000 Angstroms by atmospheric pressure chemical vapor deposition (APCVD).

In an embodiment, the patterning exposes a region of the polysilicon layer 404 adjacent a region of the first dopant source 408, as depicted in FIG. 6. In one embodiment, forming and patterning the first dopant source 408 includes forming and patterning a layer of boron silicate glass (BSG). In a specific embodiment, the BSG layer is formed by chemical vapor deposition as a uniform, blanket layer and then patterned by a lithography and etch process. In a particular such embodiment, the BSG layer is formed by a chemical vapor deposition technique such as, but not limited to, atmospheric pressure chemical vapor deposition (APCVD), plasma-enhanced chemical vapor deposition (PECVD), low-pressure chemical vapor deposition (LPCVD), or ultra-high vacuum chemical vapor deposition (UHVCVD). In an alternative specific embodiment, the BSG layer is deposited already having a pattern and, thus, the forming and patterning are performed simultaneously. In one such embodiment, the patterned BSG layer is formed by a screen-printing approach. In one embodiment, the first dopant source 408 is a layer of film that includes P-type dopant impurity atoms and can be deposited above a substrate. In an alternate embodiment, an ion implantation approach may be used.

In one embodiment, lower P-type doping in the polysilicon layer results by lowering the dopant amount in a BSG oxide layer (P-type dopant source). The concentration of Boron (B) in the BSG oxide layer is reduced from typical levels of ˜4% to ˜1-2%. This results in lowering the amount of P-type dopant concentration level in the polysilicon layer to ˜5E19/cm3 to ˜5E17/cm3.

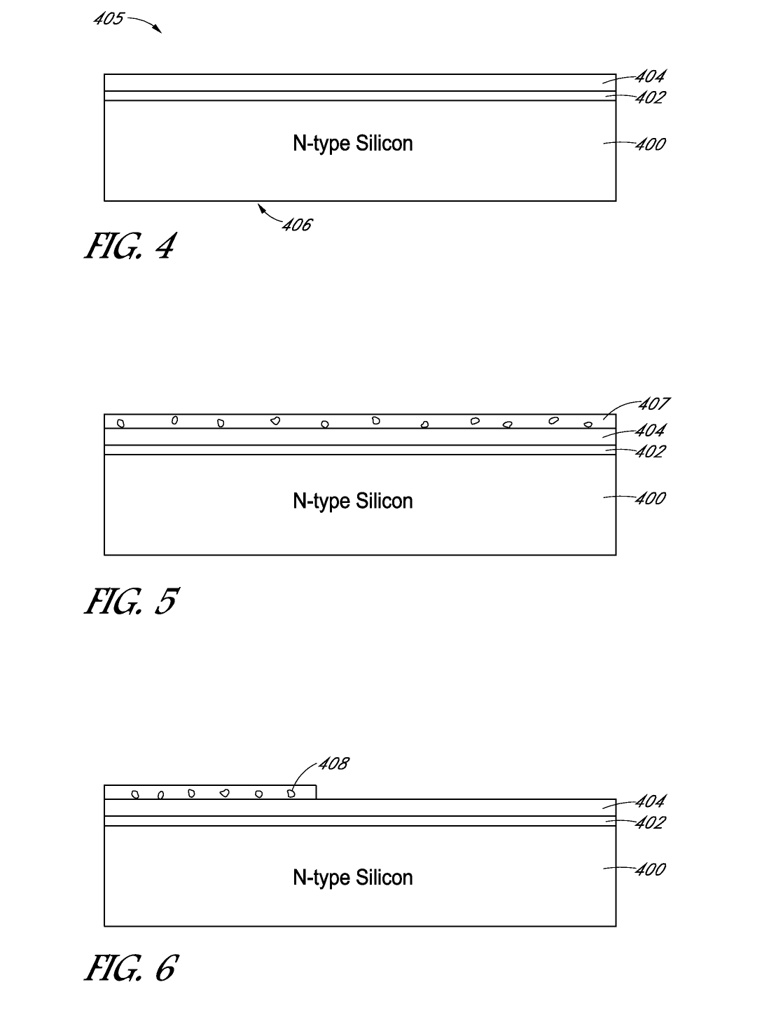

Referring to operation 310 of the flowchart 300, and to corresponding FIG. 7, forming a second doped silicon dioxide layer 410 of FIG. 7 for providing a second dopant source 412 of a second conductivity type such as N-type (e.g., Phosphorus) on the polysilicon layer 404 and above the P-type first dopant source 408 is shown. The second doped silicon dioxide layer 410 serves as a dopant source for a subsequently formed diffusion region, which is an N-type diffusion region 416 in this example (see FIG. 8). The second doped silicon dioxide layer 410 may thus be doped with an N-type dopant, such as phosphorus. The second doped silicon dioxide layer 410 may be formed to a thickness of about 2000 Angstroms by APCVD.

In one embodiment, forming the second dopant source 412 includes forming a layer of phosphorus silicate glass (PSG). In a specific embodiment, the PSG layer is formed by chemical vapor deposition as a uniform, blanket layer and then patterned by a lithography and etch process. In a particular such embodiment, the PSG layer is formed by a chemical vapor deposition technique such as, but not limited to, atmospheric pressure chemical vapor deposition (APCVD), plasma-enhanced chemical vapor deposition (PECVD), low-pressure chemical vapor deposition (LPCVD), or ultra-high vacuum chemical vapor deposition (UHVCVD). In one embodiment, the second dopant source 412 is a layer of film that includes N-type dopant impurity atoms and can be deposited above a substrate. In an alternate embodiment, an ion implantation approach may be used.

By using the PSG layer, in one embodiment, the range of N-type doping concentration level in the N-type diffusion region 416 of the polysilicon layer 404 can be about 10% of the N-type dopant source's dopant concentration level of, e.g., 1E19/cm3-1E20/cm3.

Referring to operation 312 of the flowchart 300, and to corresponding FIG. 8, heating the substrate 400 is shown. In an embodiment, the heating drives dopants from the first and second dopant sources 408 and 412. For example, in one embodiment, heating the substrate 400 drives dopants from the first and second dopant sources 408 and 412, respectively, into the polysilicon layer 404. However, in another embodiment, the first and second dopant sources 408 and 412 may be formed directly on the substrate 400 or on a thin oxide on the substrate 400, and heating the substrate 400 drives dopants from the first and second dopant sources 408 and 412, respectively, into the substrate 400. In one specific such embodiment, the substrate 400 is a bulk crystalline silicon substrate, and the first and second dopant sources 408 and 412 are formed on the bulk crystalline silicon substrate. The bulk crystalline silicon substrate is then heated to drive dopants from the first and second dopant sources 408 and 412 into the bulk crystalline silicon substrate.

In operation 312, a thermal drive-in step diffuses dopants from the first and second doped silicon dioxide layers 407, 410 to the underlying polysilicon layer 404, thereby forming P-type and N-type diffusion regions in the polysilicon layer 404, which is accordingly labeled as a P-type diffusion polysilicon region 414 and an N-type diffusion polysilicon region 416. The thermal drive-in step may be performed by heating the sample of FIG. 7. In one embodiment, drive conditions result in a heavily doped, e.g., greater than 1E20/cm3, polysilicon layer that is uniform throughout the thickness of the film and has very little doping under the polysilicon, e.g., equal to or less than 1E18/cm3. The thermal drive-in step results in the polysilicon layer 404 under the first doped silicon dioxide layer 407 forming the P-type diffusion polysilicon region 414 and polysilicon layer 404 under the second doped silicon dioxide layer 410 forming the N-type diffusion polysilicon region 416. The dopant concentration level of the P-type diffusion polysilicon region 414 may be less than the dopant concentration level of the N-type diffusion polysilicon region 416. For example, the P-type dopant concentration level may be 1E17-1E18/cm3 and the N-type dopant concentration level may be 1E19-1E20/cm3.

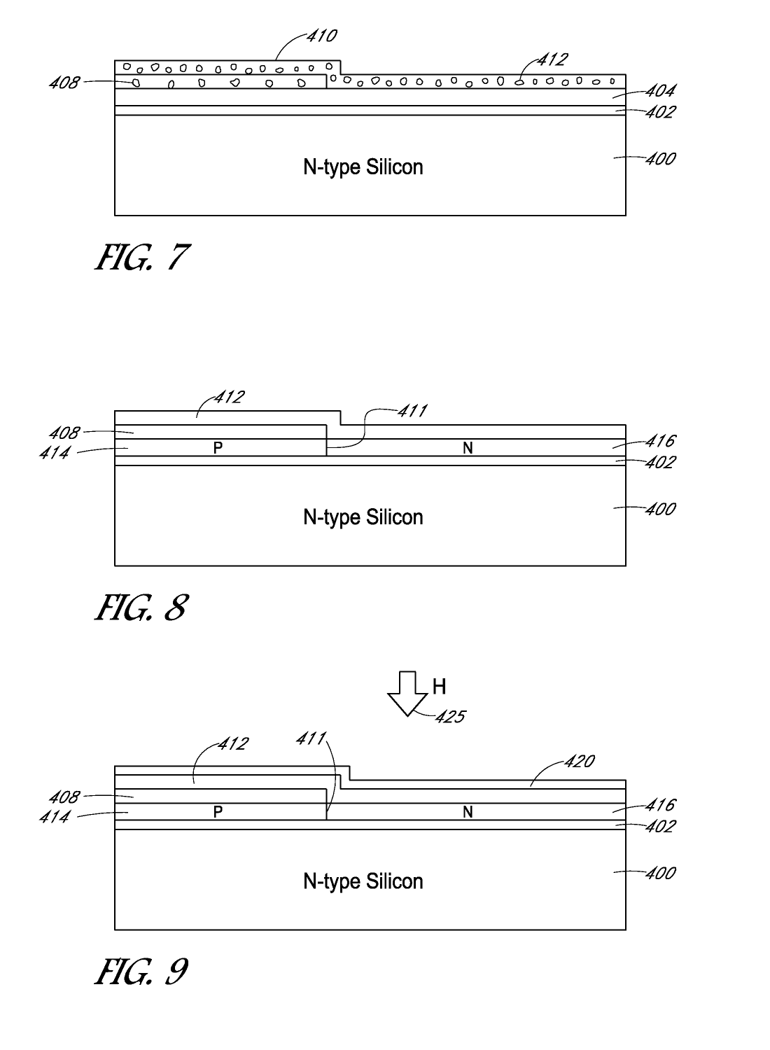

Referring to operation 314 of the flowchart 300, and to corresponding FIG. 9, forming a silicon nitride layer 420 on the second doped silicon dioxide layer 410 is shown (e.g., as in FIG. 7). Hydrogen (H), as shown by an arrow 425, generated in operation 314 may be used to passivate the butting PN junction 411 of FIG. 8.

Contact openings can be formed to provide exposure to the N-type diffusion polysilicon region 416 and to the P-type diffusion polysilicon region 414. In one embodiment, the contact openings are formed by laser ablation. Forming contacts for the back-contact solar cell can include forming conductive contacts in the contact openings for coupling the N-type diffusion polysilicon region 416 and the P-type diffusion polysilicon region 414. Thus, in an embodiment, conductive contacts are formed on or above a surface of a bulk N-type silicon substrate such as the substrate 400 opposing a light receiving surface of the substrate 400.

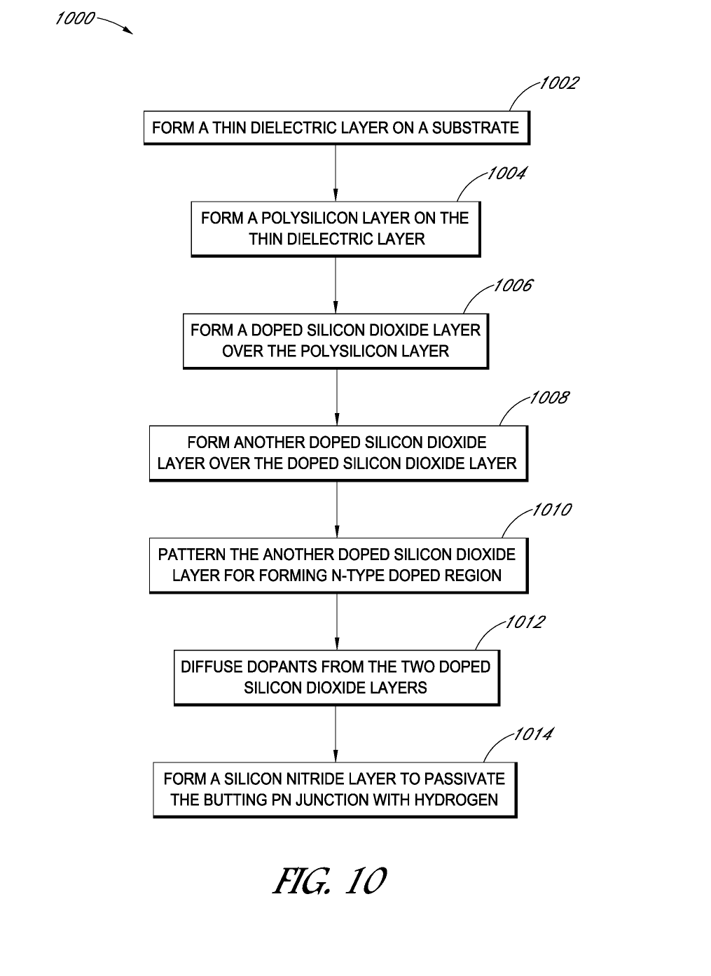

Referring to FIG. 10, a flowchart 1000 representing operations in an example method of forming P-type and N-type diffusion regions by counter doping for a back-contact solar cell is shown. FIGS. 11-16 illustrate cross-sectional views of various stages in the fabrication of a back-contact solar cell, corresponding to operations of the flowchart 1000, in accordance with an embodiment. In this example, the mentioned process steps are performed in the order shown but in other embodiments, a different order can be used. It is to be noted that other process steps not necessary for understanding are omitted in the interest of clarity. For example, other process steps, such as formation of metal contacts to the P-type and N-type diffusion regions, follow the passivation step to complete the fabrication of the solar cell. Moreover, in some embodiments, fewer than all the steps shown in FIG. 10 can be used. In various embodiments, the description of the method of FIG. 3 applies equally to the description of the method of FIG. 10. Accordingly, for clarity of explanation, some description of that description is not repeated.

When the P-type dopant level is dramatically reduced then a counter doping technique may be used for creating the N-type and P-type diffusion regions. Very low P-type diffusion with Boron may be used in a counter doping process for the areas where an N-type diffusion with Phosphorous is needed. To this end, an in situ doped P type film may be formed and then a patterned deposition with high levels of phosphorous may be performed. This will counter dope the initial P-type material to N-type. The non N-type doped areas will remain P-type. One possible patterned deposition technique that may be deployed is implant but others can work as well.

FIG. 11 shows a solar cell substrate 1100 having a backside 1105 and a front side 1106. There are a plurality of P-type diffusion regions and N-type diffusion regions in a solar cell but only one of each is shown as being fabricated in the following example for clarity of illustration.

Referring to operation 1002 of the flowchart 1000, and to corresponding FIG. 11, forming a thin dielectric layer 1102 on a backside surface of the substrate 1100 is shown. In an embodiment, the substrate 1100 is a bulk single-crystal substrate, such as an N-type doped single crystalline silicon substrate or N-type silicon wafer. The illustrated thin dielectric layer 1102 of FIG. 11 includes the same features as the thin dielectric layer 402 of FIG. 4. The illustrated substrate 1100 of FIG. 11 includes the same features as the substrate 400 of FIG. 4.

Referring to operation 1004 of the flowchart 1000, and to corresponding FIG. 11, forming an undoped polycrystalline silicon (polysilicon) layer 1104 on the thin dielectric layer 1102 is illustrated. The illustrated polysilicon layer 1104 of FIG. 11 includes the same features as the polysilicon layer 404 of FIG. 4.

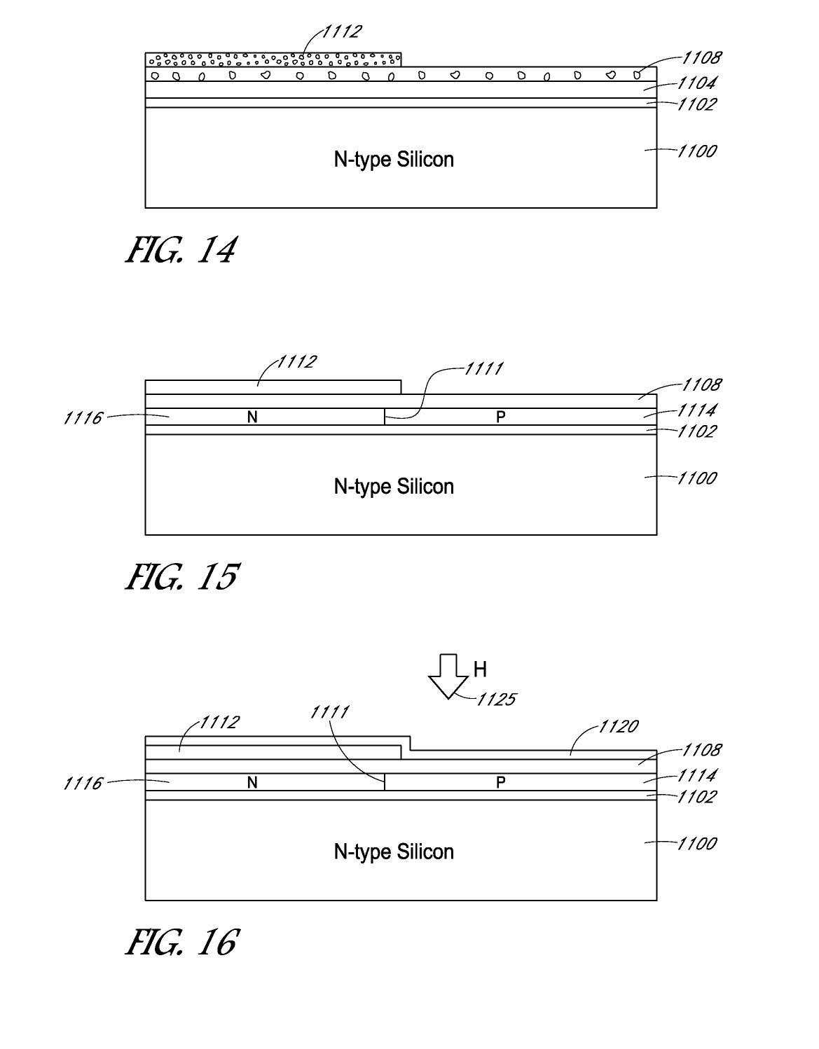

Referring to operation 1006 of the flowchart 1000, and to corresponding FIG. 12, forming a first doped silicon dioxide layer 1107 to provide a first dopant source 1108 of a first conductivity type such as P-type (e.g., Boron) on the polysilicon layer 1104 is shown. The first doped silicon dioxide layer 1107 serves as a dopant source for a subsequently formed diffusion region, which is a P-type diffusion polysilicon region 1114 (see FIG. 15) formed from a first or P-type dopant source 1108 in this example. In one embodiment, forming the first dopant source 1108 includes forming a layer of boron silicate glass (BSG). The illustrated first doped silicon dioxide layer 1107 of FIG. 11 includes the same features as the first doped silicon dioxide layer 407 of FIG. 5.

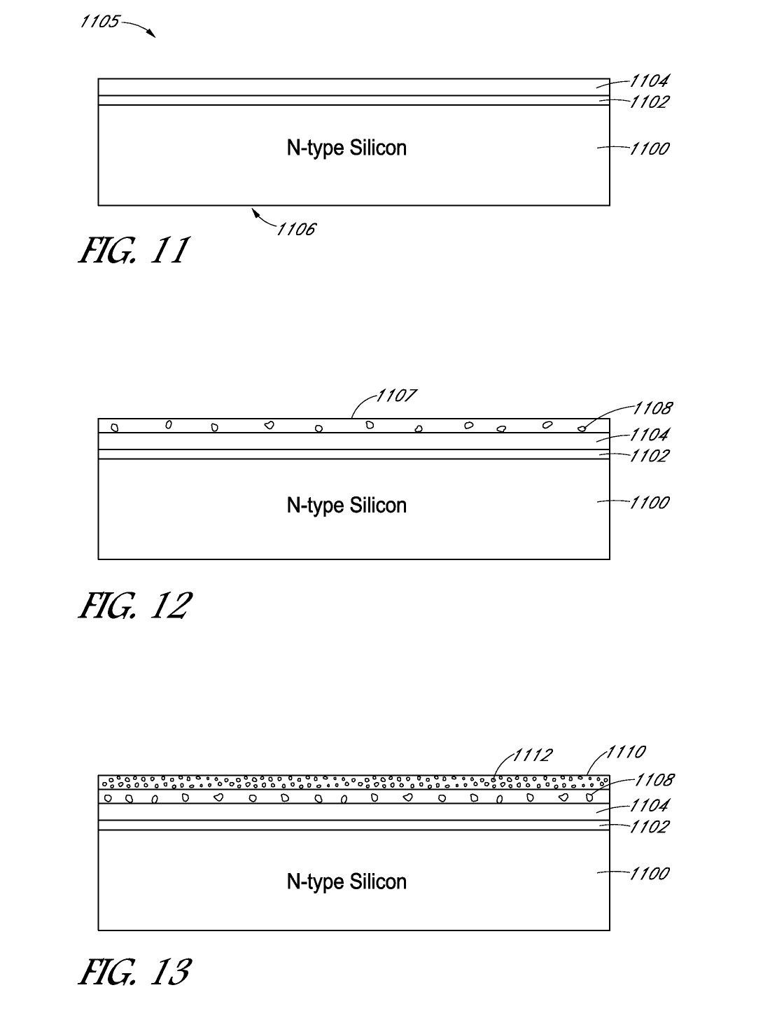

Referring to operation 1008 of the flowchart 1000, and to corresponding FIG. 13, forming a second doped silicon dioxide layer 1110 for providing a second dopant source 1112 of a second conductivity type such as N-type (e.g., Phosphorus) on the first doped silicon dioxide layer 1107 is shown. The second doped silicon dioxide layer 1110 serves as a dopant source for a subsequently formed diffusion region, which is an N-type diffusion polysilicon region 1116 in this example (see FIG. 15). In one embodiment, forming the second dopant source 1112 includes forming a layer of phosphorus silicate glass (PSG). The illustrated second doped silicon dioxide layer 1110 of FIG. 13 includes the same features as the second doped silicon dioxide layer 410 of FIG. 7.

Referring to operation 1010 of the flowchart 1000, and to corresponding FIGS. 14-15, patterning the second dopant source 1112 of a second conductivity type such as N-type (e.g., Phosphorus) on the first doped silicon dioxide layer 1107 is shown. The second doped silicon dioxide layer 1110 serves as a dopant source for a subsequently formed diffusion region, which is the N-type diffusion polysilicon region 1116 in this example (see FIG. 15). The second doped silicon dioxide layer 1110 may thus be doped with an N-type dopant, such as Phosphorous. The second doped silicon dioxide layer 1110 is patterned to remain over an area of the first doped silicon dioxide layer 1107 where the N-type diffusion polysilicon region 1116 is to be formed (FIG. 15).

Referring to operation 1012 of the flowchart 1000, and to corresponding FIG. 15, heating the substrate 1100 is performed. In one embodiment, heating the substrate 1100 drives dopants from the first and second dopant sources 1108 and 1112, respectively, into the polysilicon layer 1104. In operation 1012, a thermal drive-in step diffuses dopants from the first and second doped silicon dioxide layers 1107, 1110 to the underlying polysilicon layer 1104, thereby forming P-type and N-type diffusion regions in the polysilicon layer 1104, which is accordingly labeled as the P-type diffusion polysilicon region 1114 and the N-type diffusion polysilicon region 1116. The dopant concentration level of the P-type diffusion polysilicon region 1114 may be less than the dopant concentration level of the N-type diffusion polysilicon region 1116. For example, the P-type dopant concentration level may be 1E17-1E18/cm3 and the N-type dopant concentration level may be 1E19-1E20/cm3.

Referring to operation 1014 of the flowchart 1000, and to corresponding FIG. 16, forming a silicon nitride layer 1120 on the second doped silicon dioxide layer 1110 and the exposed first doped silicon dioxide layer 1107 of FIG. 15 is illustrated. Hydrogen (H), as shown by an arrow 1125, generated in operation 1014 may be used to passivate the butting PN junction 1111 of FIG. 15.

Contact openings can be formed to provide exposure to the N-type diffusion polysilicon region 1116 and to the plurality of P-type diffusion polysilicon region 1114. In one embodiment, the contact openings are formed by laser ablation. Forming contacts for the back-contact solar cell can include forming conductive contacts in the contact openings for coupling the N-type diffusion polysilicon region 1116 and the P-type diffusion polysilicon region 1114. Thus, in an embodiment, conductive contacts are formed on or above a surface of a bulk N-type silicon substrate such as the substrate 1100 opposing a light receiving surface of the substrate 1100.

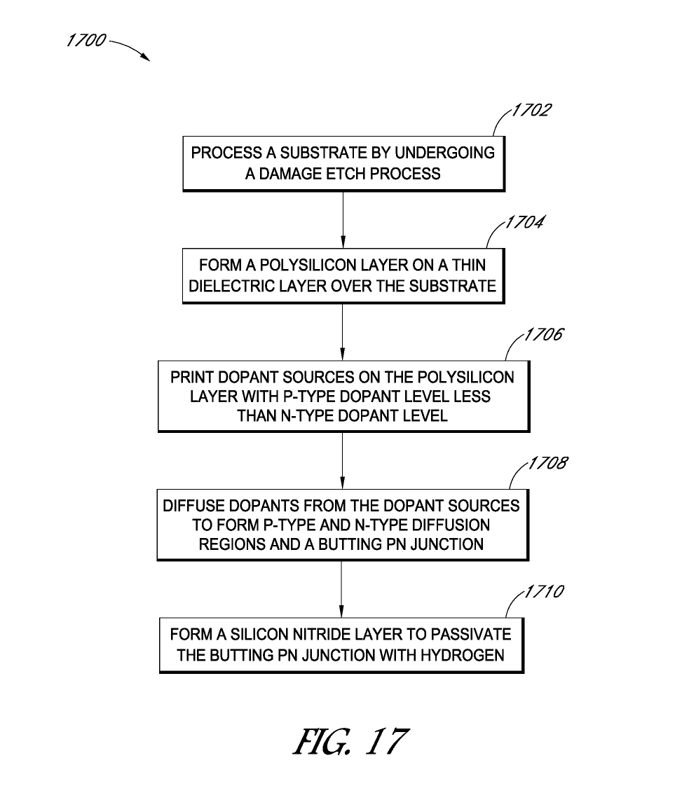

Referring to FIG. 17, a flowchart 1700 representing operations in a method of printing P-type and N-type dopant sources for a back-contact solar cell, in accordance with an embodiment of the present disclosure is shown. FIGS. 18-22 illustrate cross-sectional views of various stages in the fabrication of a back-contact solar cell, corresponding to operations of flowchart 1700, in accordance with an embodiment. FIG. 18 shows a solar cell substrate 1800 having a backside 1805 and a front side 1806. There are a plurality of P-type diffusion regions and N-type diffusion regions in a solar cell but only one of each is shown as being fabricated in the following example for clarity of illustration.

FIGS. 18-22 schematically illustrate a process that includes the following process steps: a) Damage etch step, b) Polysilicon deposition, c) Printing of dopant sources, d) Curing step, and e) Passivation. In this example, the just mentioned process steps are performed in the order shown. It is to be noted that other process steps not necessary for understanding are omitted in the interest of clarity. For example, other process steps, such as formation of metal contacts to the P-type and N-type diffusion regions, follow the passivation step to complete the fabrication of the solar cell.

Referring to operation 1702 of the flowchart 1700, and to corresponding FIG. 18, preparing the substrate 1800 for processing into a solar cell by undergoing a damage etch step is shown.

The substrate 1800 may comprise an N-type silicon wafer in this example, and is typically received with damaged surfaces due to the sawing process used by the wafer vendor to slice the substrate 1800 from its ingot. The substrate 1800 may be about 100 to 200 microns thick as received from the wafer vendor. In one embodiment, the damage etch step involves removal of about 10 to 20 μm from each side of the substrate 1800 using a wet etch process comprising potassium hydroxide. The damage etch step may also include cleaning of the substrate 1800 to remove metal contamination. Thin dielectric layers (not labeled) may be formed on the front side and backside surfaces of the substrate 1800. The thin dielectric layers may comprise silicon dioxide thermally grown to a thickness less than or equal to 20 Angstroms (e.g., 16 Angstroms) on both surfaces of the substrate 1800. The front side surface of the substrate 1800 and materials formed thereon are also referred to as being on the front side of the solar cell because they face the sun to receive solar radiation during normal operation. Similarly, the backside surface of the substrate 1800 and materials formed thereon are also referred to as being on the backside of the solar cell, which is opposite the front side.

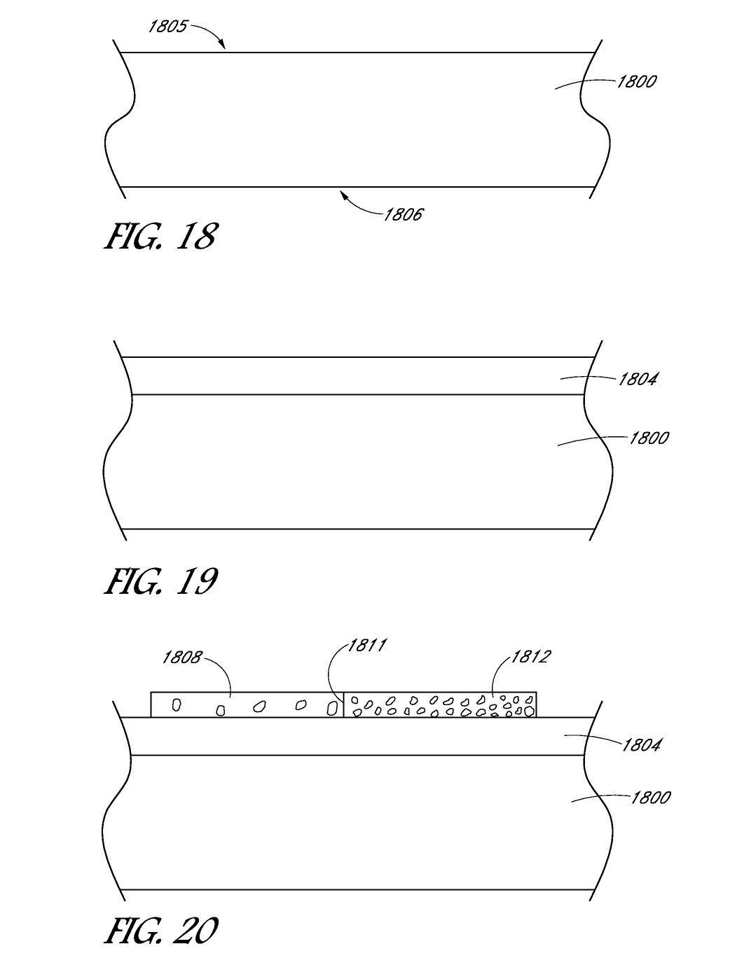

Referring to operation 1704 of the flowchart 1700, and to corresponding FIG. 19, forming a polysilicon layer 1804 on a thin dielectric layer (not shown) over the substrate 1800 is shown. The polysilicon layer 1804 is formed on the thin dielectric layer on the backside 1805 of the substrate 1800. The polysilicon layer 1804, which is undoped at this stage of the fabrication process, may be formed to a thickness of about 2200 Angstroms by LPCVD.

Referring to operation 1706 of the flowchart 1700, and to corresponding FIG. 20, printing first and second dopant sources 1808, 1812 on the polysilicon layer 1804 over the substrate 1800 is shown. As will be more apparent below, the first and second dopant sources 1808, 1812 provide dopants for forming diffusion regions in the polysilicon layer 1804 on the backside of the solar cell. Several first and second dopant sources 1808, 1812 are formed for any given solar cell, but only one of each is shown in FIG. 20 for clarity of illustration. The first and second dopant sources 1808, 1812, which comprise printable inks, have different conductivity types. In the example of FIG. 20, the first dopant source 1808 is a P-type dopant source and the second dopant source 1812 is an N-type dopant source. The first and second dopant sources 1808, 1812 are formed by printing, such as inkjet printing or screen printing. Inkjet printing can advantageously allow for printing of both first and second dopant sources 1808, 1812 in a single pass of the inkjet printer nozzle over the substrate 1800. The first and second dopant sources 1808, 1812 may also be printed in separate passes depending on the process.

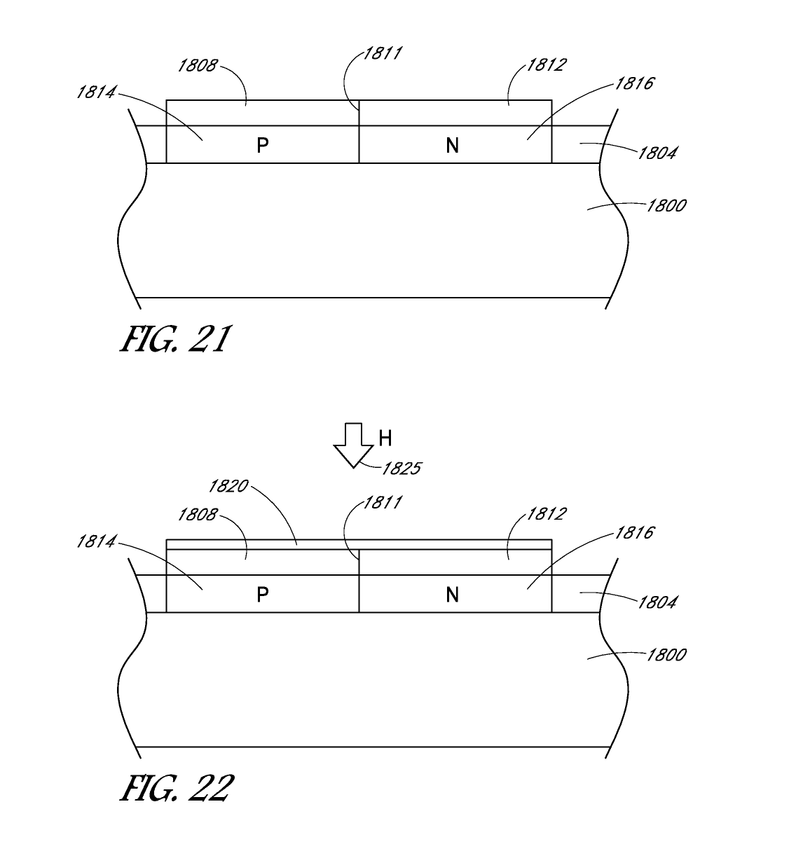

Referring to operation 1708 of the flowchart 1700, and to corresponding FIG. 21, diffusing dopants from the first and second dopant sources 1808, 1812 to form a P-type diffusion polysilicon region 1814 and an N-type diffusion polysilicon region 1816 on the polysilicon layer 1804 over the substrate 1800 is shown. For diffusing dopants, a curing step is performed to diffuse dopants from the first dopant source 1808 into the polysilicon layer 1804 to form the P-type diffusion polysilicon region 1814 in the polysilicon layer 1804, and to diffuse dopants from the second dopant source 1812 into the polysilicon layer 1804 to form the N-type diffusion polysilicon region 1816 in the polysilicon layer 1804. The curing step may be performed for about 30 minutes at a temperature range between 600° C. and 1100° C. (e.g., 950° C.).

Referring to operation 1710 of the flowchart 1700, and to corresponding FIG. 22, forming a silicon nitride layer 1820 on the printed first and second dopant sources 1808, 1812 is illustrated. Hydrogen (H), as shown by an arrow 1825, generated in operation 1710 may be used to passivate the butting PN junction 1811 of FIG. 21.

Contact openings can be formed to provide exposure to the N-type diffusion polysilicon region 1816 and to the plurality of P-type diffusion polysilicon region 1814. In one embodiment, the contact openings are formed by laser ablation. Forming contacts for the back-contact solar cell can include forming conductive contacts in the contact openings for coupling the N-type diffusion polysilicon region 1816 and the P-type diffusion polysilicon region 1814. Thus, in an embodiment, conductive contacts are formed on or above a surface of a bulk N-type silicon substrate such as the substrate 1800 opposing a light receiving surface of the substrate 1800.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

1. A solar cell, comprising:
a substrate, the substrate including a front side facing the sun to receive solar radiation during normal operation and a backside opposite the front side; and
a butting PN junction formed over the backside of the substrate between a P-type diffusion region and an N-type diffusion region, wherein the P-type diffusion region is formed from a P-type doped region including a first dopant source having a first dopant concentration level and wherein the N-type diffusion region is formed from an N-type doped region including a second dopant source having a second dopant concentration level greater than the first dopant concentration level.

2. The solar cell of claim 1, further comprising:
polysilicon formed over the backside of the substrate, wherein the P-type diffusion region and the N-type diffusion region are formed in the polysilicon.

3. The solar cell of claim 1, further comprising:
a passivation region at a boundary region of the butting PN junction.

4. The solar cell of claim 1, wherein the P-type diffusion region comprises boron having a dopant concentration level less than approximately 5E17/cm3.

5. The solar cell of claim 4, wherein the P-type diffusion region is doped at a dopant concentration level that reduces recombination at the butting PN junction to an extent that a resulting device efficiency is greater than 20%.

6. The solar cell of claim 4, wherein the N-type diffusion region comprises phosphorus having a dopant concentration level greater than approximately 10% of 1E20/cm3.

7. The solar cell of claim 1, further comprising:
a first metal contact finger coupled to the P-type diffusion region formed from the P-type doped region on the backside of the substrate; and
a second metal contact finger coupled to the N-type diffusion region formed from the N-type doped region on the backside of the substrate.

8. The solar cell of claim 1, wherein the P-type doped region and the N-type doped region are disposed over a dielectric layer over the substrate.

9. A method of fabricating a solar cell, the method comprising:
forming a P-type diffusion region over a substrate from a P-type doped region including a first dopant source having a first dopant concentration level; and
forming an N-type diffusion region over the substrate and adjacent to the P-type diffusion region from an N-type doped region including a second dopant source having a second dopant concentration level to provide a butting PN junction between the P-type diffusion region and the N-type diffusion region such that the first dopant concentration level is less than the second dopant concentration level.

10. The method of claim 9, wherein forming a butting PN junction further comprises:
forming a layer of polysilicon over a backside of the substrate, the substrate having a front side facing the sun to receive solar radiation during normal operation, the backside opposite the front side;
forming the P-type doped region on the layer of polysilicon; and
forming the N-type doped region on the layer of polysilicon.

11. The method of claim 9, further comprising:
diffusing dopants from the P-type doped region to form the P-type diffusion region on the substrate;
diffusing dopants from the N-type doped region to form the N-type diffusion region on the substrate; and
forming the P-type and N-type diffusion regions external to the substrate and over a dielectric layer.

12. The method of claim 9, further comprising:
passivating a boundary region of the butting PN junction using Hydrogen.

13. The method of claim 9, wherein diffusing dopants from the P-type doped region further comprises:
using boron as a P-type dopant source at a dopant concentration level less than 1E17/cm3.

14. The method of claim 13, wherein diffusing dopants from the N-type doped region further comprises:
using phosphorus as an N-type dopant source at a dopant concentration level greater than 1E20/cm3.

15. The method of claim 9, further comprising:
printing the P-type and N-type doped regions using a printable ink

16. The method of claim 10, further comprising:
electrically coupling a first metal contact finger to the P-type diffusion region on the backside of the substrate; and
electrically coupling a second metal contact finger to the N-type diffusion region on the backside of the substrate.

17. The method of claim 9, further comprising:
depositing in situ doped P-type polysilicon to form the P-type diffusion region; and
forming the N-type diffusion region by counter doping dopants from the second dopant source with a masked N-type diffusion.

18. A solar cell, comprising:
a substrate, the substrate including a front side facing the sun to receive solar radiation during normal operation and a backside opposite the front side; and
a polysilicon layer formed over the backside of the substrate; and
a P-type diffusion region and an N-type diffusion region formed in the polysilicon layer, wherein a butting PN junction is formed between the P-type diffusion region and the N-type diffusion region, wherein the P-type diffusion region has a first dopant concentration level and the N-type diffusion region has a second dopant concentration level greater than the first dopant concentration level.

19. The solar cell of claim 1, wherein the first dopant concentration level of the P-type diffusion region is less than approximately 5E17/cm3.

20. The solar cell of claim 1, wherein a concentration ratio from a P-type dopant source used to form the P-type diffusion region to an N-type dopant source used to form the N-Type diffusion region is approximately 1:100.
